(19) United States
(12) Patent Application Publication
(10) Pub. No.: US 2024/0055507 A1
(43) Pub. Date: Feb. 15, 2024

(54) ELECTROSTATIC DISCHARGE PROTECTION CIRCUIT

(71) Applicant: MACRONIX INTERNATIONAL CO., LTD., Hsinchu (TW)

(72) Inventor: Shih-Yu WANG, Taipei City (TW)

(21) Appl. No.: 17/819,367

(22) Filed: Aug. 12, 2022

(51) Int. Cl. H01L 29/74; H01L 29/06

(52) U.S. Cl. CPC H01L 29/7436; H01L 29/0692; H02H 9/046

(57) ABSTRACT

An electrostatic discharge protection circuit includes a N type region, a P type component, a P type region, a N type element, a first conductive terminal, a second conductive terminal, a power clamp circuit and a conductive pad. The P type component is in the N type region. The N type element is in the P type region. The first conductive terminal is electrically connected to the N type region. The second conductive terminal is electrically connected to the P type region and the N type element. The power clamp circuit is electrically connected between the first conductive terminal and the second conductive terminal. The conductive pad is electrically connected to the P type component.

### BACKGROUND

### Technical Field

The disclosure relates to an electrostatic discharge protection circuit.

### Description of the Related Art

In the design of the semiconductor devices, due to human body discharge or machine discharge, the electrostatic current caused by an electrostatic discharge (ESD) event easily causes damage to the internal circuit. Therefore, an electrostatic discharge protection circuit needs to be provided in the semiconductor device to achieve the purpose of electrostatic discharge protection.

### SUMMARY

The present disclosure relates to an electrostatic discharge protection circuit.

According to an embodiment, an electrostatic discharge protection circuit is provided. The electrostatic discharge protection circuit comprises a N type region, a P type component, a P type region, a N type element, a first conductive terminal, a second conductive terminal, a power clamp circuit and a conductive pad. The P type component is in the N type region. The N type element is in the P type region. The first conductive terminal is electrically connected to the N type region. The second conductive terminal is electrically connected to the P type region and the N type element. The power clamp circuit is electrically connected between the first conductive terminal and the second conductive terminal. The conductive pad is electrically connected to the P type component.

According to another embodiment, an electrostatic discharge protection circuit is provided. The electrostatic discharge protection circuit comprises a P type region, a N type component, a N type region, a P type element, a first conductive terminal, a second conductive terminal, a power clamp circuit and a conductive pad. The N type component is in the P type region. The P type element is in the N type region. The first conductive terminal is electrically connected to the P type element and the N type region. The second conductive terminal is electrically connected to the P type region. The power clamp circuit is electrically connected between the first conductive terminal and the second conductive terminal. The conductive pad is electrically connected to the N type component.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1A illustrates a cross-section view of an electrostatic discharge protection circuit of a first embodiment.

FIG. 1B illustrates a top view of an electrostatic discharge protection circuit of the first embodiment.

FIG. 1C illustrates an electrostatic discharge protection circuit and current paths according to an embodiment.

FIG. 1D illustrates an electrostatic discharge protection circuit and current paths according to an embodiment.

FIG. 2A illustrates a cross-section view of an electrostatic discharge protection circuit of a second embodiment.

FIG. 2B illustrates a top view of an electrostatic discharge protection circuit of the second embodiment.

FIG. 3 illustrates a cross-section view of an electrostatic discharge protection circuit of a third embodiment.

FIG. 4A illustrates a cross-section view of an electrostatic discharge protection circuit of a fourth embodiment.

FIG. 4B illustrates a top view of an electrostatic discharge protection circuit of the fourth embodiment.

FIG. 5A illustrates a cross-section view of an electrostatic discharge protection circuit of a fifth embodiment.

FIG. 5B illustrates a top view of an electrostatic discharge protection circuit of the fifth embodiment.

FIG. 6 illustrates a cross-section view of an electrostatic discharge protection circuit of a sixth embodiment.

FIG. 7A illustrates a cross-section view of an electrostatic discharge protection circuit of a seventh embodiment.

FIG. 7B illustrates a top view of an electrostatic discharge protection circuit of the seventh embodiment.

FIG. 8A illustrates a cross-section view of an electrostatic discharge protection circuit of an eighth embodiment.

FIG. 8B illustrates a top view of an electrostatic discharge protection circuit of the eighth embodiment.

FIG. 9A illustrates a cross-section view of an electrostatic discharge protection circuit of a ninth embodiment.

FIG. 9B illustrates a top view of an electrostatic discharge protection circuit of the ninth embodiment.

### DETAILED DESCRIPTION

The present disclosure relates to an electrostatic discharge protection circuit and an operating/using method of which. The illustrations may not be necessarily drawn to scale, and there may be other embodiments of the present disclosure which are not specifically illustrated. Thus, the specification and the drawings are to be regard as an illustrative sense rather than a restrictive sense. Moreover, the descriptions disclosed in the embodiments of the disclosure such as detailed construction, manufacturing steps and material selections are for illustration only, not for limiting the scope of protection of the disclosure. The steps and elements in details of the embodiments could be modified or changed according to the actual needs of the practical applications. The disclosure is not limited to the descriptions of the embodiments. The illustration uses the same/similar symbols to indicate the same/similar elements.

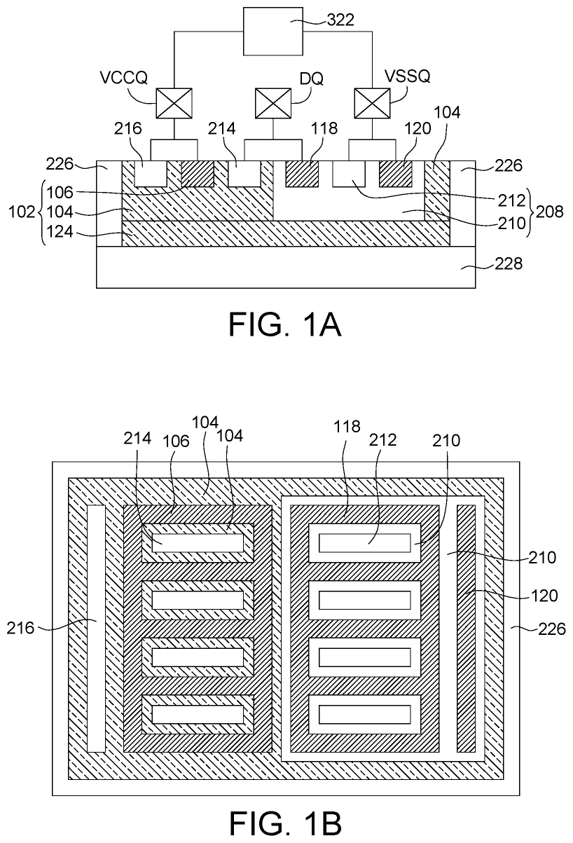

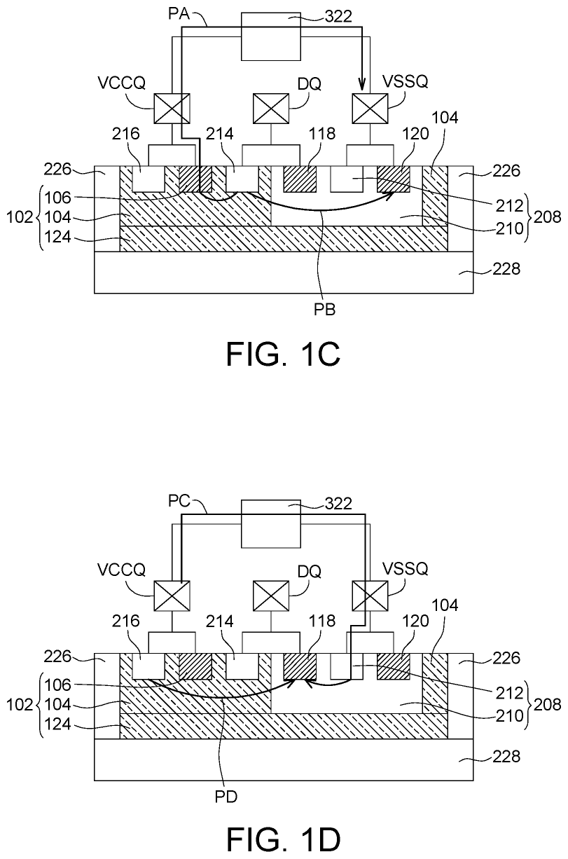

FIG. 1A and FIG. 1B are referred to, which illustrate a cross-section view and a top view of an electrostatic discharge (ESD) protection circuit of a first embodiment respectively. A N type region 102 comprise a N type well 104 and a N type component 106. The N type component 106 is in the N type well 104. A P type region 208 comprises a P type well 210 and a P type component 212. The P type component 212 is in the P type well 210. The N type region 102 is adjacent to the P type region 208. The N type well 104 is adjacent to the P type well 210.

A P type component 214 is in the N type well 104. A P type element 216 is in the N type well 104. The N type component 106, the P type component 214 and the P type element 216 are separated from each other by the N type well 104. The N type component 106, the P type component 214 and the P type element 216 may be doped regions formed in the N type well 104 by an ion implantation method. A N type dopant concentration of the N type component 106 may be higher than a N type dopant concentration of the N type well 104. The N type component 106 may be a N type heavily doped region (such as a N+ doped region). The P type component 214 and the P type element 216 may be P type heavily doped regions (such as P+ doped regions).

A N type component 118 is in the P type well 210. A N type element 120 is in the P type well 210. The P type component 212, the N type component 118 and the N type element 120 are separated from each other by the P type well 210. The P type component 212, the N type component 118 and the N type element 120 may be doped regions formed in the P type region 208 by an ion implantation method. A P type dopant concentration of the P type component 212 may be higher than a P type dopant concentration of the P type well 210. The P type component 212 may be a P type heavily doped region (such as a P+ doped region). The N type component 118 and the N type element 120 may be N type heavily doped regions (such as N+ doped regions)

A power clamp circuit 322 (ESD clamp circuit) is electrically connected between a first conductive terminal VCCQ and a second conductive terminal VSSQ. The first conductive terminal VCCQ is electrically connected to the N type component 106 of the N type region 102. The first conductive terminal VCCQ is electrically connected to the P type element 216. The second conductive terminal VSSQ is electrically connected to the P type component 212 of the P type region 208. The second conductive terminal VSSQ is electrically connected to the N type element 120. The first conductive terminal VCCQ is a power input terminal. The second conductive terminal VSSQ is a ground terminal. A conductive pad DQ is electrically connected to the P type component 214. The conductive pad DQ is electrically connected to the N type component 118.

The N type region 102 may further comprise a N type deep well 124. The N type well 104 and the P type well 210 are on the N type deep well 124. The N type well 104 may surround on a sidewall of the P type well 210. A P type well 226 may surround on sidewalls of the N type well 104 and the N type deep well 124. The N type deep well 124 and the P type well 210 may be on a P type substrate 228.

As shown in FIG. 1B, the P type well 226 and the N type element 120 have a strip shape and have an identical extending direction. The P type component 214 and the P type component 212 have a strip shape and have an identical extending direction. The extending direction of the P type well 226 and the N type element 120 is perpendicular to the extending direction of the P type component 214 and the P type component 212. The N type component 106 and the N type component 118 have a grid shape. The N type component 106 having the grid shape surrounds the P type component 214 having the strip shape. The N type component 118 having the grid shape surrounds the P type component 212 having the strip shape.

FIG. 10 illustrates a current path PA and a current path PB from the conductive pad DQ to the second conductive terminal VSSQ of the electrostatic discharge protection circuit. As to the current path PA, a current from the conductive pad DQ flows through the P type component 214, the N type well 104, the N type component 106, the first conductive terminal VCCQ and the power clamp circuit 322 in sequence, and then flows to the second conductive terminal VSSQ. The P type component 214 and the N type region 102 (comprising the N type well 104 and the N type component 106) form a diode (parasitic diode). The current path PB comprises a silicon controlled rectifier (parasitic silicon controlled rectifier) formed by the P type component 214, the N type region 102, the P type region 208 and the N type element 120. The base-emitter of the PNP structure of the silicon controlled rectifier from the conductive pad DQ to the second conductive terminal VSSQ is forward, which can help the silicon controlled rectifier to turn on to be in a conduction mode. The silicon controlled rectifier of the conduction mode allows the current from the conductive pad DQ flows through the P type component 214, the N type well 104 of the N type region 102, the P type well 210 of the P type region 208 and the N type element 120 in sequence, and then flows to the second conductive terminal VSSQ, forming the current path PB. The current path PA comprising the diode and the power clamp circuit may attribute a high voltage drop on input and output buffers. At the same time, the current path PB comprising the silicon controlled rectifier (SCR) can reduce the voltage drop. The structure of the electrostatic discharge protection circuit of FIG. 10 may be similar with the structure of the electrostatic discharge protection circuit of FIG. 1A. The occurrences of current path PA and the current path PB from the conductive pad DQ to the second conductive terminal VSSQ illustrated with referring to FIG. 10 are not limited to the structure shown in FIG. 1A and FIG. 10.

FIG. 1D illustrates a current path PC and a current path PD from the first conductive terminal VCCQ to the conductive pad DQ of the electrostatic discharge protection circuit. As to the current path PC, a current from the first conductive terminal VCCQ flows through the power clamp circuit 322, the second conductive terminal VSSQ, the P type component 212, the P type well 210, the N type component 118 in sequence, and then flows to the conductive pad DQ. The N type component 118 and the P type region 208 (comprising the P type well 210 and the P type component 212) form a diode (parasitic diode). The current path PD comprises a silicon controlled rectifier (parasitic silicon controlled rectifier) formed by the P type element 216, the N type region 102, the P type region 208 and the N type component 118. The base-emitter of the NPN structure of the silicon controlled rectifier from the first conductive terminal VCCQ to the conductive pad DQ is forward, which can help the silicon controlled rectifier to turn on to be in a conduction mode. The silicon controlled rectifier of the conduction mode allows the current from the first conductive terminal VCCQ flows through the P type element 216, the N type well 104 of the N type region 102, the P type well 210 of the P type region 208 and the N type component 118 in sequence, and then flows to the conductive pad DQ, forming the current path PD. The current path PC comprising the diode and the power clamp circuit may attribute a high voltage drop on input and output buffers. At the same time, the current path PD comprising the silicon controlled rectifier can reduce the voltage drop. The structure of the electrostatic discharge protection circuit of FIG. 1D may be similar with the structure of the electrostatic discharge protection circuit of FIG. 1A. The occurrences of current path PC and the current path PD from the first conductive terminal VCCQ to the conductive pad DQ illustrated with referring to FIG. 1D are not limited to the structure shown in FIG. 1A and FIG. 1D.

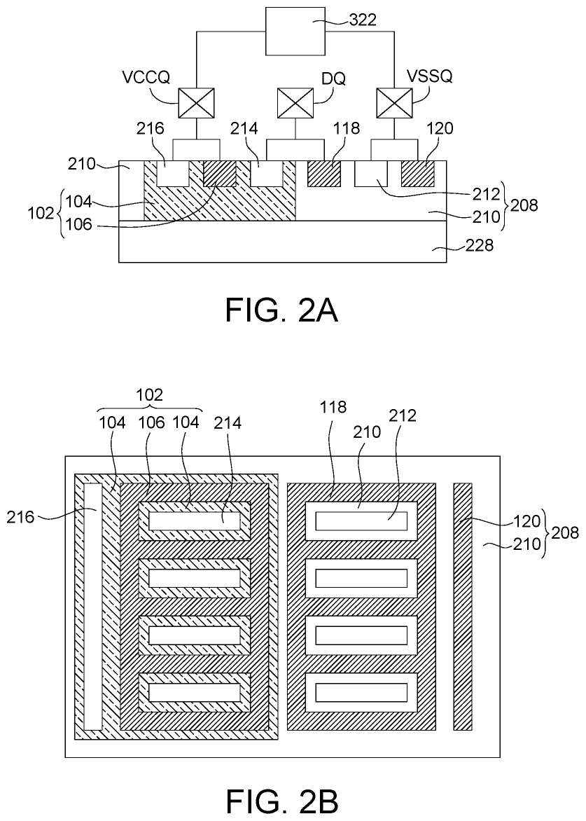

FIG. 2A and FIG. 2B are referred to, which illustrate a cross-section view and a top view of an electrostatic discharge protection circuit of a second embodiment respectively. The electrostatic discharge protection circuit of the second embodiment is different from the electrostatic discharge protection circuit of the first embodiment in structure with the following description. The P type well 210 of the P type region 208 surrounds on the sidewall of the N type well 104 of the N type region 102. The P type well 210 and the N type well 104 are on the P type substrate 228. The electrostatic discharge protection circuit of the second embodiment can comprise the current path PA and the current path PB from the conductive pad DQ to the second conductive terminal VSSQ illustrated with referring to FIG. 10. The electrostatic discharge protection circuit of the second embodiment can comprise the current path PC and the current path PD from the first conductive terminal VCCQ to the conductive pad DQ illustrated with referring to FIG. 1D.

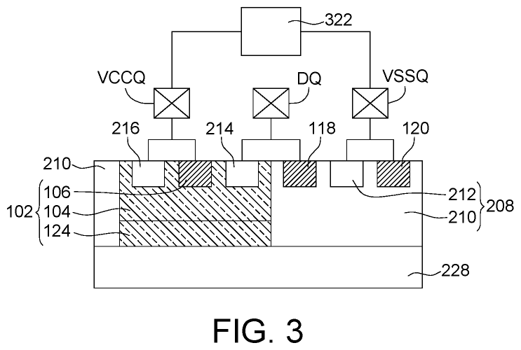

FIG. 3 is referred to, which illustrate a cross-section view of an electrostatic discharge protection circuit of a third embodiment. The electrostatic discharge protection circuit of the third embodiment is different from the electrostatic discharge protection circuit of the second embodiment in structure with the following description. The N type well 104 of the N type region 102 is on the N type deep well 124. The P type well 210 of the P type region 208 surrounds on the sidewalls of the N type well 104 and the N type deep well 124. The P type well 210 and the N type deep well 124 are on the P type substrate 228. A top view of the electrostatic discharge protection circuit of the third embodiment may be similar with FIG. 2B. The electrostatic discharge protection circuit of the third embodiment can comprise the current path PA and the current path PB from the conductive pad DQ to the second conductive terminal VSSQ illustrated with referring to FIG. 10. The electrostatic discharge protection circuit of the third embodiment can comprise the current path PC and the current path PD from the first conductive terminal VCCQ to the conductive pad DQ illustrated with referring to FIG. 1D.

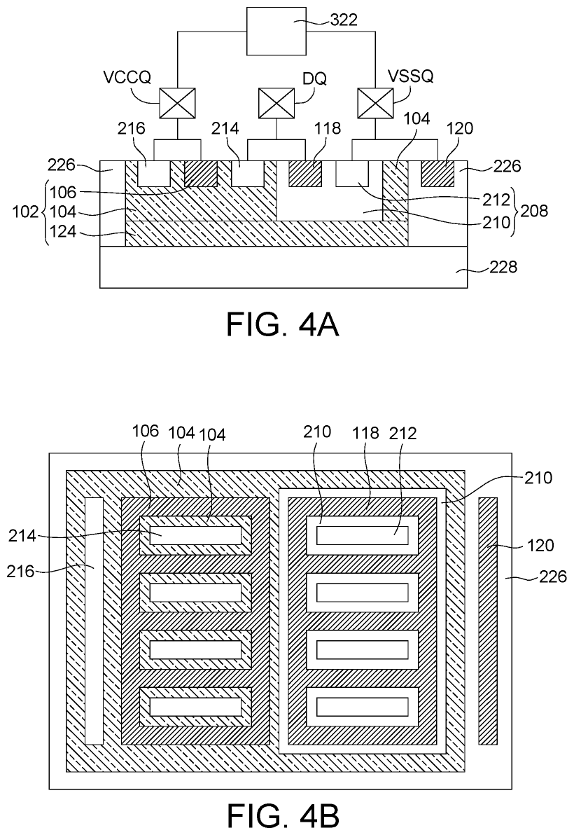

FIG. 4A and FIG. 4B are referred to, which illustrate a cross-section view and a top view of an electrostatic discharge protection circuit of a fourth embodiment respectively. The electrostatic discharge protection circuit of the fourth embodiment is different from the electrostatic discharge protection circuit of the first embodiment in structure with the following description. The N type element 120 is in the P type well 226. The N type element 120 is separated from the P type component 212 and the N type component 118 by the N type well 104, the P type well 210 and P the P type well 226. The electrostatic discharge protection circuit of the fourth embodiment can comprise the current path PC and the current path PD from the first conductive terminal VCCQ to the conductive pad DQ illustrated with referring to FIG. 1D.

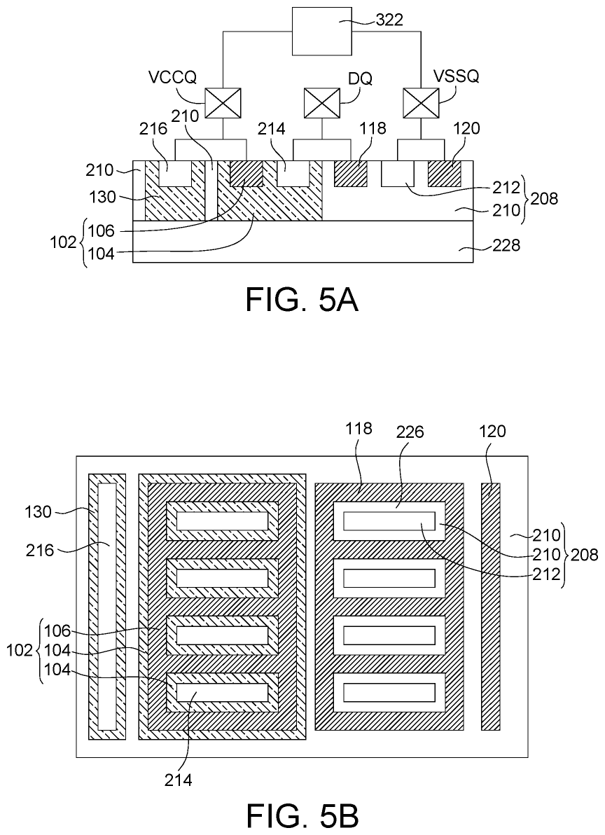

FIG. 5A and FIG. 5B are referred to, which illustrate a cross-section view and a top view of an electrostatic discharge protection circuit of a fifth embodiment respectively. The electrostatic discharge protection circuit of the fifth embodiment is different from the electrostatic discharge protection circuit of the first embodiment in structure with the following description. The P type element 216 is in a N type well 130. The N type well 130 and the N type well 104 are separated from each other by the P type well 210. The P type element 216 is separated from the N type component 106 and the P type component 214 by the N type well 130, the N type well 104 and the P type well 210. The P type well 210 surrounds on the sidewall of the N type well 130. The P type well 210 surrounds on the sidewall of the N type well 104. The P type well 210, the N type well 104 and the N type well 130 are on the P type substrate 228. The electrostatic discharge protection circuit of the fifth embodiment can comprise the current path PA and the current path PB from the conductive pad DQ to the second conductive terminal VSSQ illustrated with referring to FIG. 10.

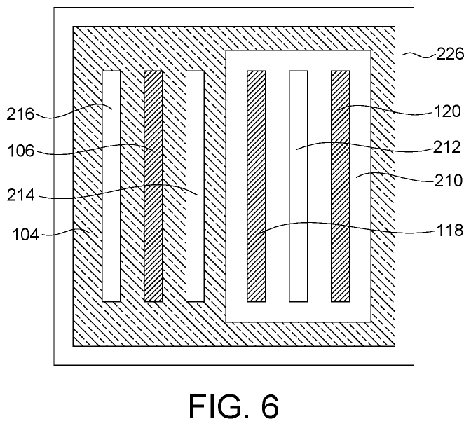

FIG. 6 is referred to, which illustrates a top view of an electrostatic discharge protection circuit of a sixth embodiment respectively. The top view of the electrostatic discharge protection circuit in FIG. 6 is different from the top view of the electrostatic discharge protection circuit in FIG. 1B with the following description. The P type well 226, the N type component 106, the P type component 214, the N type component 118, the P type component 212 and the N type element 120 all have a strip shape and have an identical extending direction. The N type component 106 is between the P type component 214 and the P type element 216. The P type component 212 is between the N type component 118 and the N type element 120. A cross-section view of the electrostatic discharge protection circuit of the sixth embodiment may be similar with FIG. 1A.

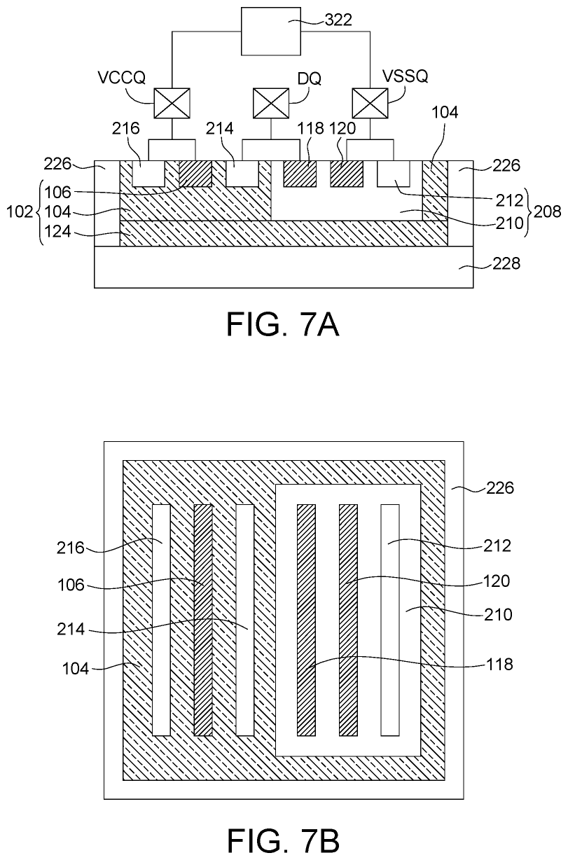

FIG. 7A and FIG. 7B are referred to, which illustrate a cross-section view and a top view of an electrostatic discharge protection circuit of a seventh embodiment respectively. The electrostatic discharge protection circuit of the seventh embodiment is different from the electrostatic discharge protection circuit of the first embodiment in structure with the following description. The N type component 106 is between the P type component 214 and the P type element 216. The N type element 120 is between the N type component 118 and the P type component 212. As shown in FIG. 7B, the P type well 226, the N type component 106, the P type component 214, the N type component 118, the P type component 212 and the N type element 120 all have a strip shape and have an identical extending direction. The electrostatic discharge protection circuit of the seventh embodiment can comprise the current path PA and the current path PB from the conductive pad DQ to the second conductive terminal VSSQ illustrated with referring to FIG. 10. The electrostatic discharge protection circuit of the seventh embodiment can comprise the current path PC and the current path PD from the first conductive terminal VCCQ to the conductive pad DQ illustrated with referring to FIG. 1D.

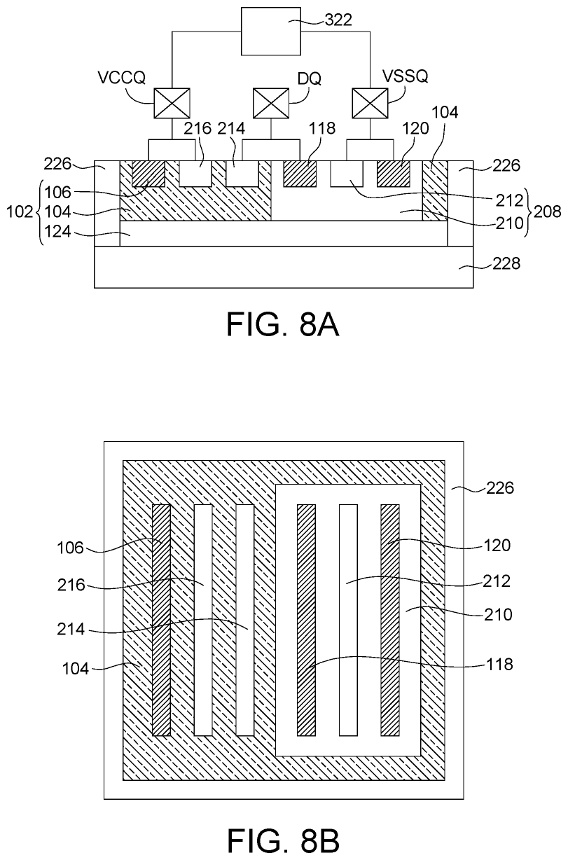

FIG. 8A and FIG. 8B are referred to, which illustrate a cross-section view and a top view of an electrostatic discharge protection circuit of an eighth embodiment respectively. The electrostatic discharge protection circuit of the eighth embodiment is different from the electrostatic discharge protection circuit of the seventh embodiment in structure with the following description. The P type element 216 is between the N type component 106 and the P type component 214. The P type component 212 is between the N type component 118 and the N type element 120. The electrostatic discharge protection circuit of the eighth embodiment can comprise the current path PA and the current path PB from the conductive pad DQ to the second conductive terminal VSSQ illustrated with referring to FIG. 10. The electrostatic discharge protection circuit of the eighth embodiment can comprise the current path PC and the current path PD from the first conductive terminal VCCQ to the conductive pad DQ illustrated with referring to FIG. 1D.

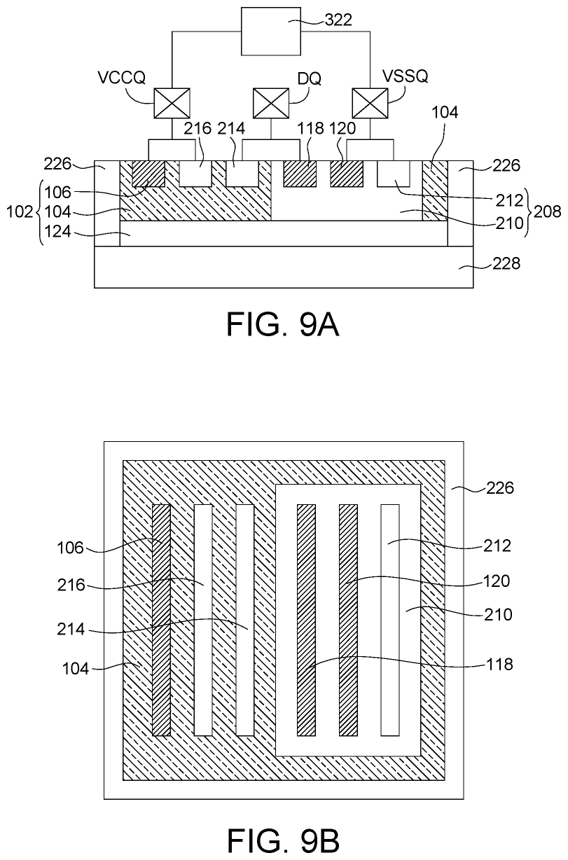

FIG. 9A and FIG. 9B are referred to, which illustrate a cross-section view and a top view of an electrostatic discharge protection circuit of a ninth embodiment respectively. The electrostatic discharge protection circuit of the ninth embodiment is different from the electrostatic discharge protection circuit of the eighth embodiment in structure with the following description. The N type element 120 is between the N type component 118 and the P type component 212. The electrostatic discharge protection circuit of the ninth embodiment can comprise the current path PA and the current path PB from the conductive pad DQ to the second conductive terminal VSSQ illustrated with referring to FIG. 10. The electrostatic discharge protection circuit of the ninth embodiment can comprise the current path PC and the current path PD from the first conductive terminal VCCQ to the conductive pad DQ illustrated with referring to FIG. 1D.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An electrostatic discharge protection circuit, comprising:
a N type region;
a P type component in the N type region;
a P type region;
a N type element in the P type region;
a first conductive terminal electrically connected to the N type region;
a second conductive terminal electrically connected to the P type region and the N type element;
a power clamp circuit electrically connected between the first conductive terminal and the second conductive terminal; and
a conductive pad electrically connected to the P type component.

2. The electrostatic discharge protection circuit according to claim 1, wherein the P type component, the N type region, the P type region and the N type element form a silicon controlled rectifier.

3. The electrostatic discharge protection circuit according to claim 1, wherein an electrostatic discharge current flows through the conductive pad, the P type component, the N type region, the P type region, the N type element and the second conductive terminal in sequence.

4. The electrostatic discharge protection circuit according to claim 1, wherein the N type region and the P type component form a diode.

5. The electrostatic discharge protection circuit according to claim 1, wherein an electrostatic discharge current flows through the conductive pad, the P type component, the N type region, the first conductive terminal, the power clamp circuit and the second conductive terminal in sequence.

6. The electrostatic discharge protection circuit according to claim 1, wherein the first conductive terminal is a power input terminal, the second conductive terminal is a ground terminal.

7. The electrostatic discharge protection circuit according to claim 1, wherein the N type region comprises:
a N type well; and
a N type component in the N type well, wherein the P type component is in the N type well, the first conductive terminal is electrically connected to the N type component.

8. The electrostatic discharge protection circuit according to claim 1, wherein the P type region comprises:
a P type well; and
a P type component in the P type well, wherein the second conductive terminal is electrically connected to the P type component.

9. The electrostatic discharge protection circuit according to claim 1, further comprising a P type element in the N type region, wherein the first conductive terminal is electrically connected to the P type element.

10. The electrostatic discharge protection circuit according to claim 1, further comprising a N type component in the P type region, wherein the conductive pad is electrically connected to the N type component.

11. An electrostatic discharge protection circuit, comprising:
a P type region;
a N type component in the P type region;
a N type region;
a P type element in the N type region;
a first conductive terminal electrically connected to the P type element and the N type region;
a second conductive terminal electrically connected to the P type region;
a power clamp circuit electrically connected between the first conductive terminal and the second conductive terminal; and
a conductive pad electrically connected to the N type component.

12. The electrostatic discharge protection circuit according to claim 11, wherein the P type region and the N type component form a diode.

13. The electrostatic discharge protection circuit according to claim 11, wherein an electrostatic discharge current flows through the first conductive terminal, the power clamp circuit, the second conductive terminal, the P type region, the N type component and the conductive pad in sequence.

14. The electrostatic discharge protection circuit according to claim 11, wherein the P type element, the N type region, the P type region and the N type component form a silicon controlled rectifier.

15. The electrostatic discharge protection circuit according to claim 11, wherein an electrostatic discharge current flows through the first conductive terminal, the P type element, the N type region, the P type region, the N type component and the conductive pad in sequence.

16. The electrostatic discharge protection circuit according to claim 11, wherein the P type region comprises:
a P type well; and
a P type component in the P type well, wherein the N type component is in the P type well, the second conductive terminal is electrically connected to the P type component.

17. The electrostatic discharge protection circuit according to claim 11, wherein the first conductive terminal is a power input terminal, the second conductive terminal is a ground terminal.

18. The electrostatic discharge protection circuit according to claim 11, wherein the N type region comprises:
a N type well; and
a N type component in the N type well, wherein the first conductive terminal is electrically connected to the N type component.

19. The electrostatic discharge protection circuit according to claim 11, further comprising a P type component in the N type well, wherein the conductive pad is electrically connected to the P type component.

20. The electrostatic discharge protection circuit according to claim 11, further comprising a N type element, wherein the P type region comprises:
a P type well; and
a P type component in the P type well, wherein the N type element is in the P type well, the second conductive terminal is electrically connected to the N type element.
